(19) United States
(12) Patent Application Publication
(10) Pub. No.: US 2010/0326849 A1
(43) Pub. Date: Dec. 30, 2010

(54) OUTDOOR UMBRELLA SYSTEM WITH INTEGRATED SOLAR POWER SUPPLY

(76) Inventors: Gregory D. Trimarche, Irvine, CA (US); Curt Crandall, Laguna Beach, CA (US)

Correspondence Address: Luce, Forward, Hamilton & Scripps LLP, 2050 Main Street, Suite 600, Irvine, CA, 92614, US

(21) Appl. No.: 12/830,201

(22) Filed: Jul. 2, 2010

Related U.S. Application Data
(63) Continuation-in-part of application No. 12/113,820, filed on May 1, 2008.
(60) Provisional application No. 60/915,299, filed on May 1, 2007.
(60) Provisional application No. 61/013,935, filed on Dec. 14, 2007.

(51) Int. Cl. B65D 71/00; H01L 31/042; A45B 25/00

(52) U.S. Cl. 206/223; 136/244; 135/16

(57) ABSTRACT

Briefly stated, a pool to be assembled and emplaced in a slightly concaved location is available in a container. Similarly, an integrated beach cart and cooler system can house the self-assembly pool, and various other articles enabling parents to travel to and from the beach. Process, products and electronic commerce methods thereby are likewise disclosed, allowing consumers to make informed choices to review and purchase the instant teachings conveniently. A customer rewards function is exchanged for data-sharing about age and size of children to allow creation of a database of children for ongoing monitoring of upcoming purchasing needs. The integrated beach cart and cooler system may comprise an outdoor umbrella including a plurality of photovoltaic cells disposed on the upper surface of the umbrella.

### RELATED APPLICATIONS

This application is a continuation-in-part of and claims the benefit of and full Paris Convention priority of U.S. patent application Ser. No. 12/113,820, filed May 1, 2008, which claims the benefit of and full Paris Convention priority of U.S. Provisional Application Ser. Nos. 60/915,299, filed May 1, 2007 and 61/013,935, filed Dec. 14, 2007, the contents of each of which are incorporated by reference herein in its entirety. All Paris Convention rights are expressly reserved with respect to the instant filing and said priority claims.

### BACKGROUND OF THE DISCLOSURE

The present disclosure relates to temporary, leisure based play activities and entertainment systems, particularly for children. The present disclosure teaches how to transport and create pools at the beach, or any setting having analogous local climate and geography.

The present disclosure is directed to pools easily constructible by any parent and readily removable, in a temporary setting, particularly the beach. In particular, the present invention relates to systems, portable kits, processes and products to enable pools to be readily transported, un-packed, set-up, and re-packed. Likewise, given the nature of the instant teachings, an integrated beach cart and cooler functions well in combination with the same.

Known portable pools, for example, those for children, are generally comprised of a rigid shell. This makes it inconvenient to transport them over distance, for example from one's home or vehicle to the beach. Likewise, having mechanisms which support parental supervision at the beach without losing the freedom and nature inherent in said space have become a longstanding need in the field. These issues are addressed by the teachings of the instant disclosure. Being able to transport the container or bucket which house the foldable pool is yet another benefit of the instant teachings.

In contradiction to the disclosure herein, other portable systems cannot be folded into single containers. Modular systems are also known, but none are commercially available which would allow a parent to go to the beach without so many moving parts as to lower the relaxation value of the trip. No systems combining these two desiderata are known, or could be found, or have any commercially available counterparts. Accordingly, the teachings of the present disclosure are offered for consideration to address the ongoing need for beach pools for children, toddlers, infants and those for whom the foreboding nature of the surf may be dangerous.

### SUMMARY OF THE DISCLOSURE

Briefly stated, a pool to be assembled and emplaced in a slightly concaved location is available in a container. Process, products and e-commerce related methods thereby are disclosed. Likewise, a combination integrated beach cart and cooler functions ideally with the present disclosure.

The present inventors have discovered that longstanding needs are satisfied by a pool to be assembled and emplaced in a slightly concaved location made available in a container. Processes, products and methods thereby are disclosed, such that parents can assemble a pool at the beach.

The present disclosure permits a portable system to be easily packed-up and carried, for example to the beach, where a user simply and efficiently assembles and fills (and later disassembles) it, allowing children to swim in it without leaving the security of the zone where waves do not crash.

According to embodiments of the present disclosure a portable system to be easily laid out by removing and unfolding a foldable sheet from a portable kit and placing the sheet within a concave location and optionally reinforcing the perimeter with stakes and filling with water, is disclosed. A process for creating a portable and temporary beach pool, comprising, in combination providing a foldable sheet effective to be housed within a bucket-like container; supplying a flexible border assembly, including looped aperture creating attachments disposed about the circumference thereof, which defines a perimeter for the foldable sheet, whereby sand from a beach surface is separated from an inner pool space by the border assembly; further providing a plurality of stake members likewise housed within the bucket-like container; aligning the foldable sheet and flexible border assembly at a desired location, on an appropriate substrate, within a concave area; and attaching the foldable sheet and flexible border assembly to the appropriate substrate by driving the stake members through the looped aperture creating attachments until a tensioned pool-device is created.

According to embodiments there is provided a kit, comprising, in combination at least a container having a handle, divided into upper and lower halves by a trough defining an extension past the outer surface of the container; a foldable sheet/liner having flexible plastic tubing disposed about its perimeter which is bracingly received by the trough of the bucket in transit; a plurality of plastic stake members easily arranged in the lower half of the container beneath the foldable sheet/liner; and directions for use and accessories likewise housed within the at least a container.

According to embodiments, there is provided a kit as discussed above and claimed below, wherein said liner/foldable sheet is offered in at least one size selected from ranges of at least about three feet in diameter to about five feet in diameter.

Embodiments of an integrated beach cart and cooler may include space to transport an outdoor umbrella incorporating photovoltaic cells to shield users from the sun at the beach or other outdoor recreational areas and provide electrical power to charge small electronic devices and food and beverage coolers. In exemplary embodiments, the outdoor umbrella may include photovoltaic cells to generate energy for charging a cooler for food and drink or small personal electronic devices such as cell phones and personal digital assistants. Embodiments of an outdoor umbrella comprise a base, a support shaft mounted to the base, an awning frame slidably mounted to a top end of the support shaft, an awning mounted on the awning frame, and a plurality of photovoltaic cells disposed on the awning. The awning includes an upper surface and a lower surface, and the photovoltaic cells are disposed on the upper surface of the awning to be exposed to sunlight. The plurality of photovoltaic cells may cover substantially the entire surface of the awning and may be integrated with the top surface of the awning.

The photovoltaic cells are sufficient in number and efficiency to generate at least 0.1 watts of power. In exemplary embodiments, the photovoltaic cells are thin-film cells. The outdoor umbrella may further comprise a storage battery in electrical connection with the plurality of photovoltaic cells. The storage battery may be mounted on the base and may be adapted to store electrical energy converted by the photovoltaic cells to supply the electrical energy to one or more of a cell phone, a personal digital assistant and a food and beverage cooler.

Embodiments of the disclosure include a kit that comprises, in combination, a container having a handle, a foldable sheet/liner, a plurality of plastic stake members, an outdoor umbrella and directions for use and accessories likewise housed within the container. The container is divided into upper and lower halves by a trough defining an extension past the outer surface of the container. The foldable sheet/liner has flexible plastic tubing disposed about its perimeter which is bracingly received by the trough of the bucket in transit. The plastic stake members easily arranged in the lower half of the container beneath the foldable sheet/liner. The outdoor umbrella has a base, a support shaft mounted to the base, an awning frame slidably mounted to a top end of the support shaft, an awning mounted on the awning frame, and a plurality of photovoltaic cells disposed on the awning. The awning has a top and bottom surface. The plurality of photovoltaic cells are thin-film cells and may be integrated with the top surface of the awning. The kit may also comprise a storage battery in electrical connection with the plurality of photovoltaic cells. The storage battery may be adapted to store electrical energy converted by the photovoltaic cells to supply the electrical energy to one or more of: a cell phone, a personal digital assistant and a food and beverage cooler.

Embodiments of the disclosure also include processes for generating electrical energy. Exemplary processes comprise the steps of providing a base, a support shaft mounted to the base, an awning frame slidably mounted to a top end of the support shaft, and an awning mounted on the awning frame, supplying a plurality of photovoltaic cells, integrating the plurality of photovoltaic cells into the awning and generating electrical energy from the plurality of photovoltaic cells. The plurality of photovoltaic cells are thin-film cells. Processes also may include the step of providing a battery adapted to store electrical energy converted by the photovoltaic cells to supply the electrical energy to one or more of: a cell phone, a personal digital assistant and a food and beverage cooler.

### DRAWINGS

The above-mentioned features and objects of the present disclosure will become more apparent with reference to the following description taken in conjunction with the accompanying drawings wherein like reference numerals denote like elements and in which:

FIG. 1 is schematic of the instant disclosure as set up on a beach;

FIG. 2 is a schematic of the instant disclosure in a first state, where it is assembled in a container, according to teachings of the instant embodiments;

FIG. 3 is a side view of an outdoor umbrella, according to teachings of the instant embodiments; and

FIG. 4 is perspective view of an outdoor umbrella, according to teachings of the instant embodiments.

### DETAILED DESCRIPTION

The present inventor has discovered that temporary pool structures can be carried in a single container and un-packed and assembled, for example at the beach, with a small number of parts, which structure can be disassembled and re-packed simply and efficiently. Likewise, in combination with an integrated beach cart and cooler, a parent can pick up the pool, food and beverages and be able to travel to a beach while supervising young children.

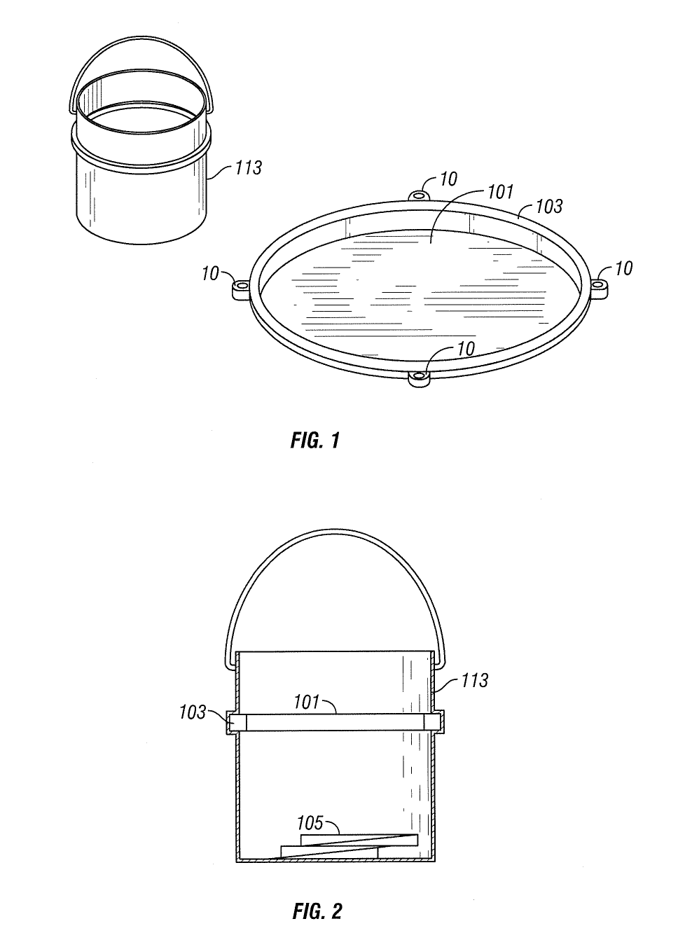

Referring now to FIG. 1, there is shown a schematic of the pool in an assembled state. Liner/foldable sheet 101, is bordered by perimeter strip 103, and held in place by stakes 105 through apertures 108 loops for attaching stakes. Water (not shown), is easily transported with any conventional vessel, or container 113, which houses liner/foldable sheet 101 and also is used to excavate depression to hold liner. By way of example, the depth can be controlled so that an infant, toddler, or older child can be monitored, cooled, and allowed to play on a blanket/towel away from the surf.

Referring now also to FIG. 2, container 113 is effective for housing the Liner/foldable sheet 101, including perimeter strip 103, and stakes 105. Artisans will understand that un-packing and re-packing liner/foldable sheet 101, including perimeter strip 103, and stakes 105, is easily done. Those skilled in the art readily understand that those sizes needed for children from the toddler stage on can be made with the teachings of the present disclosure. Likewise, the present inventors have assembled a suite of products, including an improved cooler which functions along with the teachings of the present disclosure. Spaces above stakes 105 allow for the storage of other articles and their respective transport.

Similarly, other aspects of those products offered herein are compatible with a suite of leisure products, including disposable and biodegradable beach toys and cutlery and various other items, which can be transported with, used with and otherwise function with the instant disclosure.

FIG. 2 also shows container 113 and liner/foldable sheet 101, parameter strip 103 and stakes as arranged in one embodiment. Artisans understand that the “bucket” shown is but one embodiment of the instant teachings.

Conventional children's toy sets may be adapted for use as the instant system, for example, elements of the Prince Lionhart.TM. brand of POPUPS.RTM. tent, with minor modifications, can be used to create the foldable sheet set, if structural members are removed. Those skilled in the art will understand that being foldable, and easily assembled, disassembled, and reassembled are integral functions of the instant system. Similarly, Velcro.RTM. be and of closure systems, zippers, and the like fastener are contemplated by the instant disclosure. Owing to the simplicity and ease of operations, one can use the system of the present disclosure, clean it and put it away for next time. The elegance of the system by any parent, is easily appreciated.

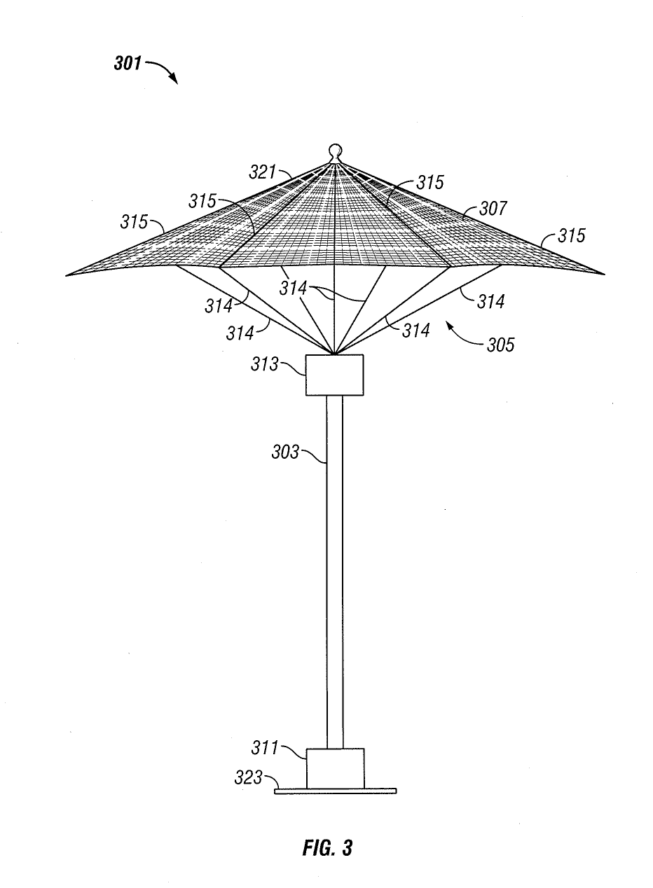

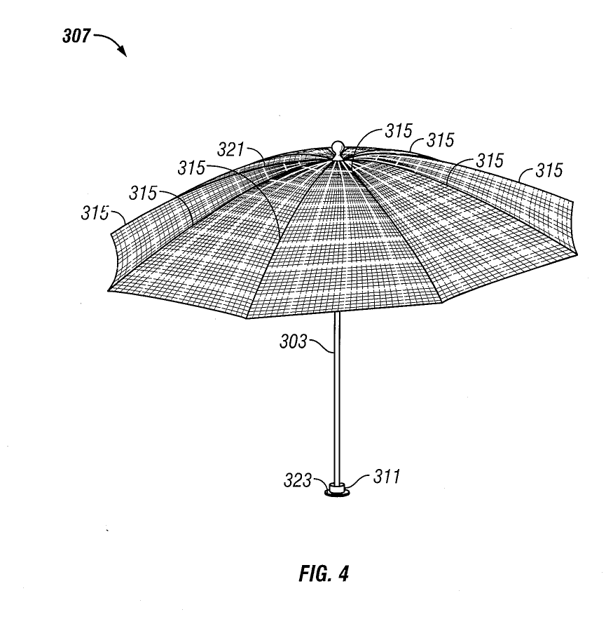

Referring to FIGS. 3-4, embodiments of an outdoor umbrella will now be described. The outdoor umbrella may fit into the above-described container 113 for ease of transport. Exemplary embodiments of an outdoor umbrella include photovoltaic cells to generate energy for charging a cooler for food and drink or small personal electronic devices such as cell phones and personal digital assistants. Outdoor umbrella 301 comprises a support shaft 303, an awning frame 305, an awning 307 and other suitable frame and support components. Support shaft 303 is mounted substantially vertically on top of base 311. Awning frame 305 is slidably mounted on the top end of support shaft 303 and includes a housing 313 and a plurality of support ribs 314 and support arms 315. The frame components may be made from any suitable material, including but not limited to, wood, metal, aluminum, steel or fiberglass.

Awning 307 is mounted on awning frame 305 such that support arms 315 support the awning 307. The support arms 315 extend radially outward from housing 313 to support the awning 307 and may be foldable between an extended position and a folded position. Awning 307 has an upper surface 317 exposed to the sunlight when the umbrella is unfolded and a lower surface 319. The awning may be made from any suitable natural or synthetic fabric, such as nylon, nylon taffeta and may include an acrylic coating on the underside and a scotch-guard type finish on the top.

A plurality of photovoltaic cells 321 are disposed on the upper surface 317 of awning 307. Photovoltaic cells 321 may be selected from any type of cell that can convert light into electricity by any such process now known or heretofore discovered. The photovoltaic cells may be silicon-based or made of other materials such as copper indium gallium selenide or cadmium telluride. They may be composed of substantially hard, soft, thick or thin material. Exemplary embodiments use thin-film photovoltaic cells, such as those made by First Solar, Global Solar Energy or Miasole, which can be employed in conjunction with flexible substrates and integrated into umbrella awning materials.

Embodiments of the disclosure may include flexible thin film photovoltaic cells in accordance with products and processes described in U.S. Patent Application Publication No. 2010/0031997, which is hereby incorporated by reference in its entirety, and/or flexible solar panel modules such as those described in U.S. Patent Application Publication No. 2010/0101627, which is hereby incorporated by reference in its entirety. Exemplary embodiments could use lightweight photovoltaic tensile structures, such as those made by FTL Solar, which are pre-fabricated tensile solar fabrics that combine fabric and thin-film photovoltaics. Embodiments of these tensile structures with integrated photovoltaic cells could be provided in accordance with products and processes described in International Patent Application No. PCT/US2009/051249, published as International Publication No. WO/2010/011649, which is hereby incorporated by reference in its entirety.

Alternatively, solar inks or dyes could be incorporated into the umbrella awning, by producing solar cells with conductive ink such as, for example, in accordance with products and processes described in U.S. Patent Application Publication No. 2005/0247340, which is hereby incorporated by reference in its entirety. In exemplary embodiments, the photovoltaic cells 321 are integrated with the top surface 317 of the awning 307. It should be understood that the awning may be entirely or almost entirely made using photovoltaic cells. A fully integrated awning would thus comprise a sheet of thin-film photovoltaic cells in the form of an umbrella awning.

Such a photovoltaic-integrated awning could be made by, for example, fabricating polysilicon photovoltaic cells on a flexible substrate suitable for use as an umbrella awning using inkjet printing or spray coating, in accordance with products and processes described in U.S. Patent Application Publication No. 2009/0155459, which is hereby incorporated by reference in its entirety. Flexible substrates that can accommodate photovoltaic cells and serve as an umbrella awning include metal foils, metal films and polymer films. For example, polycrystalline or microcrystalline silicon photovoltaic cells could be deposited on such flexible substrates using liquid silane, by employing inkjet printing or other commercial printing techniques including but not limited to screen printing, roller coating, gravure coating, curtain coating, spray coating and others. Alternatively, after the silicon photovoltaic cells are deposited on the flexible substrate, the cells and substrate could be fastened to the awning material.

To make a photovoltaic-integrated umbrella awning using thin-film semiconductor materials such as CIGS and amorphous silicon the photovoltaic cells would be separately manufactured using known methods and then electrically interconnected by stringing them or shingling them to form strings of cells. The photovoltaic cell strings are interconnected to form circuits, which may be laminated. The lamination process comprises packaging circuits in a transparent and flexible encapsulant to seal the photovoltaic circuits into a module. Examples of materials that can be used as encapsulants are fluoropolymers such as ethylene vinyl acetate copolymer, thermoplastic polyurethanes and silicones. Polymeric sheets may be used to form a barrier to moisture. The resulting flexible modules or sheets of photovoltaic cells may be cut into appropriate sizes and shapes to form an umbrella awning. Extra backing layers can be added to reinforce the strength of the awning.

The photovoltaic cells in awning 307 have a power output of between about 0.1 watts and about 3 watts, and in exemplary embodiments, provide between about 0.5 watts and about 2 watts of power. Power output in this range provides a trickle charge suitable to maintain operation of small personal electronic devices such as cell phones and personal digital assistants and could provide a full charge over the course of about 5 to 10 hours.

The outdoor umbrella may further comprise a storage battery 323 in electrical connection with the photovoltaic cells 321. The storage battery may be mounted on the support stem and may be adapted to collect and store electrical energy converted by the photovoltaic cells to supply the electrical energy to one or more of a cell phone, a personal digital assistant and a food and beverage cooler. Any suitable rechargeable battery or combination of batteries may be used, including but not limited to, lithium ion, nickel cadmium and others. A suitable lithium ion battery would be rated at 3.7 volts and 1,000 milliamp hours. The photovoltaic cells output and battery output may be configured in series or in parallel. A switching mechanism may be provided to determine whether the output power is drawn from the battery, the photovoltaic cells or both.

Those skilled in the art readily understand that electronic commerce enables customers to “surf the net” and find desired articles. According to the instant teachings customers or potential clients may view the articles of the present invention. Since catalogs and advertisements often do not show exactly how wonderful items are, the instant system also uses retail outlets housing the goods to show and tell to prospective users. Likewise, in exchange for providing information about children's age and sizes (enabling seller to track when new items may be acquired), credits, give-a-ways, or other customer rewards may be issued.

While the apparatus and method have been described in terms of what are presently considered to be the most practical and preferred embodiments, it is to be understood that the disclosure need not be limited to the disclosed embodiments. It is intended to cover various modifications and similar arrangements included within the spirit and scope of the claims, the scope of which should be accorded the broadest interpretation so as to encompass all such modifications and similar structures. The present disclosure includes any and all embodiments of the following claims.

It should also be understood that a variety of changes may be made without departing from the essence of the invention. Such changes are also implicitly included in the description. They still fall within the scope of this invention. It should be understood that this disclosure is intended to yield a patent covering numerous aspects of the invention both independently and as an overall system and in both method and apparatus modes.

Further, each of the various elements of the invention and claims may also be achieved in a variety of manners. This disclosure should be understood to encompass each such variation, be it a variation of an embodiment of any apparatus embodiment, a method or process embodiment, or even merely a variation of any element of these.

Particularly, it should be understood that as the disclosure relates to elements of the invention, the words for each element may be expressed by equivalent apparatus terms or method terms—even if only the function or result is the same.

Such equivalent, broader, or even more generic terms should be considered to be encompassed in the description of each element or action. Such terms can be substituted where desired to make explicit the implicitly broad coverage to which this invention is entitled.

It should be understood that all actions may be expressed as a means for taking that action or as an element which causes that action.

Similarly, each physical element disclosed should be understood to encompass a disclosure of the action which that physical element facilitates.

Any patents, publications, or other references mentioned in this application for patent are hereby incorporated by reference. In addition, as to each term used it should be understood that unless its utilization in this application is inconsistent with such interpretation, common dictionary definitions should be understood as incorporated for each term and all definitions, alternative terms, and synonyms such as contained in at least one of a standard technical dictionary recognized by artisans and the Random House Webster's Unabridged Dictionary, latest edition are hereby incorporated by reference.

Finally, all references listed in the Information Disclosure Statement or other information statement filed with the application are hereby appended and hereby incorporated by reference; however, as to each of the above, to the extent that such information or statements incorporated by reference might be considered inconsistent with the patenting of this/these invention(s), such statements are expressly not to be considered as made by the applicant(s).

In this regard it should be understood that for practical reasons and so as to avoid adding potentially hundreds of claims, the applicant has presented claims with initial dependencies only.

Support should be understood to exist to the degree required under new matter laws—including but not limited to U.S. Patent Law 35 USC 132 or other such laws—to permit the addition of any of the various dependencies or other elements presented under one independent claim or concept as dependencies or elements under any other independent claim or concept.

To the extent that insubstantial substitutes are made, to the extent that the applicant did not in fact draft any claim so as to literally encompass any particular embodiment, and to the extent otherwise applicable, the applicant should not be understood to have in any way intended to or actually relinquished such coverage as the applicant simply may not have been able to anticipate all eventualities; one skilled in the art, should not be reasonably expected to have drafted a claim that would have literally encompassed such alternative embodiments.

Further, the use of the transitional phrase “comprising” is used to maintain the “open-end” claims herein, according to traditional claim interpretation. Thus, unless the context requires otherwise, it should be understood that the term “compromise” or variations such as “comprises” or “comprising”, are intended to imply the inclusion of a stated element or step or group of elements or steps but not the exclusion of any other element or step or group of elements or steps.

Such terms should be interpreted in their most expansive forms so as to afford the applicant the broadest coverage legally permissible.

1. An outdoor umbrella comprising:
a support shaft mounted to the base, and an awning frame slidably mounted to a top end of the support shaft;
an awning mounted on the awning frame, the awning including an upper surface and a lower surface; and
a plurality of photovoltaic cells sufficient to generate at least 0.1 watts of power, the photovoltaic cells disposed on the upper surface of the awning.

2. The outdoor umbrella of claim 1 wherein the plurality of photovoltaic cells covers substantially the entire top surface of the awning.

3. The outdoor umbrella of claim 1 wherein the plurality of photovoltaic cells is integrated with the top surface of the awning.

4. The outdoor umbrella of claim 1 wherein the photovoltaic cells are thin-film cells.

5. The outdoor umbrella of claim 1 further comprising a storage battery in electrical connection with the plurality of photovoltaic cells.

6. The outdoor umbrella of claim 5 wherein the storage battery is mounted on the base.

7. The outdoor umbrella of claim 5 wherein the storage battery is adapted to store electrical energy converted by the photovoltaic cells to supply the electrical energy to one or more of: a cell phone, a personal digital assistant and a food and beverage cooler.

8. A kit, comprising, in combination:
at least a container having a handle, divided into upper and lower halves by a trough defining an extension past the outer surface of the container;
a foldable sheet/liner having flexible plastic tubing disposed about its perimeter which is bracingly received by the trough of the bucket in transit;
a plurality of plastic stake members easily arranged in the lower half of the container beneath the foldable sheet/liner;
an outdoor umbrella having a support shaft, and an awning frame slidably mounted to a top end of the support shaft, an awning having a top and bottom surface, the awning mounted on the awning frame, and a plurality of photovoltaic cells disposed on the awning; and
directions for use and accessories likewise housed within the at least a container.

9. The kit of claim 8 wherein the plurality of photovoltaic cells are thin-film cells.

10. The kit of claim 9 wherein the plurality of photovoltaic cells is integrated with the top surface of the awning.

11. The kit of claim 8 further comprising a storage battery in electrical connection with the plurality of photovoltaic cells.

12. The kit of claim 11 wherein the storage battery is adapted to store electrical energy converted by the photovoltaic cells to supply the electrical energy to one or more of: a cell phone, a personal digital assistant and a food and beverage cooler.

13. A process for generating electrical energy, comprising:
providing a support shaft, an awning frame slidably mounted to a top end of the support shaft, and an awning mounted on the awning frame;
supplying a plurality of photovoltaic cells;
integrating the plurality of photovoltaic cells into the awning; and
generating electrical energy from the plurality of photovoltaic cells.

14. The process of claim 13 wherein the plurality of photovoltaic cells are thin-film cells.

15. The process of claim 13 further comprising providing a battery adapted to store electrical energy converted by the photovoltaic cells to supply the electrical energy to one or more of: a cell phone, a personal digital assistant and a food and beverage cooler.

16. The outdoor umbrella of claim 1 further comprising a base, the support shaft being mounted to the base.

17. The kit of claim 8 further comprising a base, the support shaft being mounted to the base.

18. The process of claim 13 further comprising the step of providing a base, the support shaft being mounted to the base.
